(19) United States
(12) Patent Application Publication
(10) Pub. No.: US 2026/0371991 A1
(43) Pub. Date: Nov. 19, 2026

(54) APPARATUS FOR EPITAXIAL DEPOSITION OR RAPID THERMAL PROCESSING

(71) Applicant: Applied Materials, Inc., Santa Clara, CA (US)

(72) Inventors: Dmitry LUBOMIRSKY, Cupertino, CA (US); Qiwei LIANG, Fremont, CA (US); Srinivas D. NEMANI, Sunnyvale, CA (US); Alan L. TSO, San Jose, CA (US); Adib KHAN, Santa Clara, CA (US); Gautam PISHARODY, Newark, CA (US); Justin GAU, Santa Clara, CA (US); Alvin VALLEJOS, Santa Clara, CA (US); Nithin Thomas ALEX, Freemont, CA (US); Prakash MANUR, Santa Clara, CA (US); Ellie Y. YIEH, San Jose, CA (US); Surajit KUMAR, San Jose, CA (US)

(21) Appl. No.: 19/674,878

(22) Filed: May 12, 2026

Related U.S. Application Data
(60) Provisional application No. 63/947,334, filed on Dec. 23, 2025.
(60) Provisional application No. 63/808,333, filed on May 19, 2025.

(51) Int. Cl. H10P 72/00; C30B 25/10; H10P 72/76

(52) U.S. Cl. CPC H10P 72/0436; C30B 25/105; H10P 72/0602; H10P 72/0606; H10P 72/7612; H10P 72/7618

(57) ABSTRACT

Embodiments of the present disclosure generally relate to semiconductor processing equipment. In one embodiment, a processing chamber includes a chamber body with a central axis and processing region, an upper lamp module, a bottom lamp module, and a magnetic lift mechanism coupled to the chamber body. The upper lamp module includes a plurality of top lamps disposed around the central axis. The bottom lamp module is disposed on a bottom side of the chamber body and separated from the processing region by a bottom window. The bottom lamp module includes a plurality of bottom lamps with a first bottom plurality of lamps and a second bottom plurality of lamps distributed azimuthally between one or more lamps of the first bottom plurality of lamps. The magnetic lift mechanism is configured to translate the substrate support ring and includes a lift ring coupled to an actuator and a substrate support ring.

### CROSS-REFERENCE TO RELATED APPLICATIONS

### Field

This application claims the benefit of U.S. Provisional Patent Application No. 63/808,333, filed on May 19, 2025, and U.S. Provisional Patent Application No. 63/947,334, filed on Dec3 23, 2025, each of which is hereby incorporated by reference in its entirety.

### BACKGROUND

### Field

Embodiments of the present invention generally relate to processing chambers, related methods, and components for gas activation and epitaxial deposition applicable for semiconductor manufacturing.

### Description of the Related Art

Semiconductor substrates are processed for a wide variety of applications, including the fabrication of integrated devices and micro-devices. One method of processing substrates includes depositing a material, such as a dielectric material or a semiconductor material, on an upper surface of the substrate. The material may be deposited in a lateral flow chamber by flowing a process gas parallel to the surface of a substrate positioned on a support, and thermally decomposing the process gas to deposit a material from the gas onto the substrate surface.

However, operations (such as epitaxial deposition operations) can be long, expensive, inefficient, and can have limited capacity, uniformity, and throughput. Moreover, chambers with large processing volumes add to the cost of operation by requiring more processing gas to fill that volume. Additionally, processing can involve thermal non-uniformity, which can hinder ultimate device performance and/or reduced throughput. For example, activation of gases can be limited and/or can involve non-uniform activation at different temperatures, which can cause limited and/or non-uniform film growth and/or dopant concentration.

Therefore, a need exists for improved apparatuses and methods in semiconductor processing.

### SUMMARY

In one or more embodiments, a processing chamber includes a chamber body with a central axis and processing region, an upper lamp module, a bottom lamp module, and a magnetic lift mechanism coupled to the chamber body. The upper lamp module includes a plurality of top lamps disposed around the central axis. The bottom lamp module is disposed on a bottom side of the chamber body and separated from the processing region by a bottom window. The bottom lamp module includes a plurality of bottom lamps with a first bottom plurality of lamps and a second bottom plurality of lamps distributed azimuthally between one or more lamps of the first bottom plurality of lamps. The magnetic lift mechanism is configured to translate the substrate support ring and includes a lift ring coupled to an actuator and a substrate support ring.

In another embodiment, a processing chamber is provided. The processing chamber includes a chamber body defining a central axis, an upper lamp module, a bottom lamp module, and a magnetic lift mechanism coupled to the chamber body. The upper lamp module includes a plurality of top lamps disposed over a top window, the top window defining a first plane, a top pyrometer surrounded by the plurality of top lamps, the top pyrometer disposed through the upper lamp module. The bottom lamp module includes a plurality of bottom lamps disposed under a bottom window, the bottom window defining a second plane about parallel to the first plane, and a lower pyrometer surrounded by the plurality of bottom lamps, the lower pyrometer disposed through the bottom lamp module. The magnetic lift mechanism is disposed proximate the bottom lamp module and includes an actuator and a lift ring coupled to the actuator. The actuator is configured to translate a substrate support between a processing position, and a transfer position. The substrate support is disposed closer to the upper lamp module in the processing position and being closer to the bottom lamp module in the transfer position.

In another embodiment, a method of substrate manufacturing is provided. The method includes disposing a substrate in a processing chamber, translating the substrate to a processing position, applying radiant energy, and measuring a first temperature of a first substrate surface with the top pyrometer and a second temperature of a second substrate surface with a lower pyrometer. The processing chamber includes an upper lamp module having an upper plurality of lamps and a top pyrometer, a bottom lamp module having a lower plurality of lamps and a lower pyrometer, and a substrate support disposed between the upper lamp module and the bottom lamp module. Translating the substrate to a processing position disposes the substrate is closer to the upper lamp module than to the bottom lamp module. Applying radiant energy simultaneously to the substrate with the upper plurality of lamps and the lower plurality of lamps, the radiant energy includes a first energy from the upper plurality of lamps, and a second energy from the lower plurality of lamps, the second energy being at least double the first energy.

In another embodiment, a method of substrate manufacturing is provided. The method includes disposing a substrate in a processing chamber, rotating the substrate support, detecting an angular position of the substrate support, and applying thermal energy to the substrate from the upper lamp module. The processing chamber includes an upper lamp module, a bottom lamp module, and a substrate support disposed between the upper lamp module and the bottom lamp module with a substrate disposed thereon. The upper lamp module includes a first group of lamps, a second group of lamps disposed concentric with the first group of lamps, the second group of lamps includes separated subgroups arranged at equal angular intervals. The substrate support includes a lift, a plurality of lift pins coupled to the lift, and a plurality of pin arms coupled to the lift. The thermal energy from the second group of lamps changes based on the detected angular position of the substrate support.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates a schematic cross-sectional view of a processing chamber in a transfer position, according to one or more embodiments.

FIG. 2 illustrates a schematic cross-sectional view of the processing chamber in a processing position, according to one or more embodiments.

FIG. 3 illustrates a schematic top view of the upper lamp module, according to one or more embodiments.

FIG. 4 illustrates a schematic top view of the bottom lamp module, according to one or more embodiments.

FIG. 5 illustrates a flow diagram of a method, according to one or more embodiments.

FIG. 6 illustrates a schematic cross-sectional view of a processing chamber in a transfer position, according to one or more embodiments.

FIG. 7 illustrates a schematic cross-sectional view of the processing chamber in a processing position, according to one or more embodiments.

FIG. 8 illustrates a schematic cross-sectional view of a processing chamber in a transfer position, according to one or more embodiments.

FIG. 9 illustrates a schematic top view of the upper lamp module, according to one or more embodiments.

FIG. 10 illustrates a flow diagram of a method, according to one or more embodiments.

FIG. 11 illustrates a schematic cross-sectional view of a processing chamber, according to one or more embodiments.

FIG. 12 illustrates a schematic cross-sectional view of a processing chamber, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to processing chambers, related methods, and components for forming uniform temperature profiles along a substrate surface applicable for semiconductor manufacturing. In one or more embodiments, the substrate is heated by top and bottom lamp modules where the bottom lamp module provides the bulk heating and the top lamp module is used to tune the applied energy to increase uniformity of film growth rates and maintain uniform temperature distributions by use of highly tunable radiant heat profiles using the embodiments of the lamp modules disclosed herein.

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

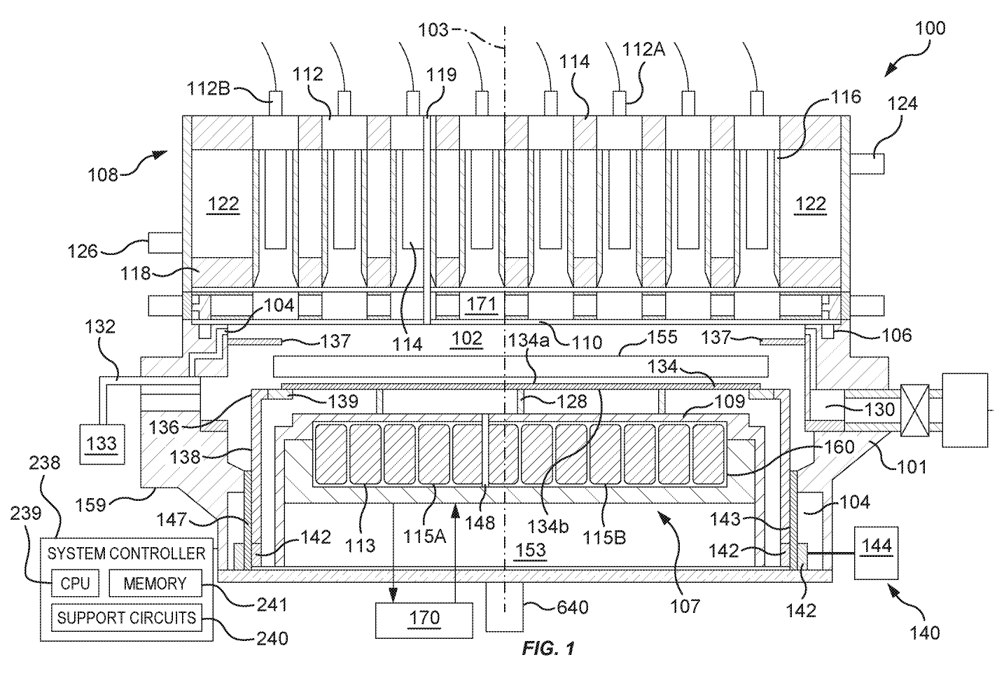

FIG. 1 illustrates a schematic cross-sectional view of a processing chamber 100, in a transfer position according to one or more embodiments.

The processing chamber 100 includes a chamber body 101 that defines a processing region 102, a central axis 103, an upper lamp module 108, and a bottom lamp module 107. The processing chamber 100 can be a reduced-pressure or vacuum chamber. The chamber body 101 at least partially defines the processing region 102. A top window 110 forms an upper wall of the processing region 102 and is sealed thereto by sealing rings 106.

In some embodiments, the processing chamber 100 functions as an epitaxy deposition chamber configured to deposit one or more layers of materials on a substrate 134. In some embodiments, the processing chamber 100 functions as a rapid thermal processing (RTP) chamber.

The upper lamp module 108 is disposed on a top side of the chamber body 101. The upper lamp module 108 is separated from the processing region 102 by the top window 110. The top window 110 is a flat transparent material configured to separate the processing region 102 from a plurality of top lamps 112 disposed in the upper lamp module 108. The plurality of top lamps 112 are disposed around the central axis 103. The plurality of top lamps 112 include a first top plurality of lamps 112A and a second top plurality of lamps 112B. The first top plurality of lamps 112A and the second top plurality of lamps 112B are further discussed below.

The bottom lamp module 107 is disposed on a bottom side of the chamber body 101. The bottom lamp module 107 is separated from the processing region 102 by a bottom window 109. The bottom lamp module 107 includes a plurality of bottom lamps 113. The plurality of bottom lamps 113 include a first bottom plurality of lamps 115A and a second bottom plurality of lamps 115B distributed azimuthally between one or more lamps of the first bottom plurality of lamps 115A.

The plurality of top lamps 112 and the plurality of bottom lamps 113 may include UV lamps, halogen lamps, laser diodes, resistive heaters, microwave powered heaters, light emitting diodes (LEDs), or any other suitable heating elements both singly or in combination. In some embodiments, the plurality of top lamps 112 and the plurality of bottom lamps 113 have an orientation parallel to the central axis 103. The bottom lamps 113 may be disposed in a lamp cavity 160 formed in bottom lamp module 107. Each plurality of lamps may be controlled independently by a controller 238 to provide desired temperature profile across the substrate 134. Each lamp of the top lamps 112 and the bottom lamps 113 is orientated parallel to the central axis 103 and includes a respective lamp tube with having reflective inner surface.

In some embodiments, the bottom lamp module 107 is coupled to a cooling system 170. The cooling system 170 is configured to maintain a temperature of the bottom window 109.

The processing chamber 100 further includes a substrate support 136 that is configured to support a substrate 134. The substrate support 136 can translate the substrate 134 within the processing region 102. In some embodiments, the substrate support 136 is a support ring that supports the substrate 134 at a radially outward edge of the substrate 134. The substrate support 136 includes a lift ring 138. The processing chamber 100 further includes chamber walls 104 adjacent the upper lamp module 108 with a preheat ring 137.

The lift ring 138 is coupled to a magnetic lift mechanism 140. The magnetic lift mechanism 140 is coupled to chamber walls 104 of the chamber body 101. The magnetic lift mechanism 140 includes a magnetic rotor disposed in a circular channel 147 around the bottom lamp module 107 and a magnetic actuator 144 located externally of the processing region 102. The magnetic lift mechanism 140 is coupled to the chamber body 101 and disposed proximate the bottom lamp module 107. The magnetic actuator 144 is magnetically coupled through a side section 159 of the chamber body 101. The magnetic actuator 144 induces rotation of the magnetic rotor which causes the lift ring 138 to lift and rotate the substrate 134 supported on the substrate support 136. In some embodiments, the substrate support 136 includes a support ring 139.

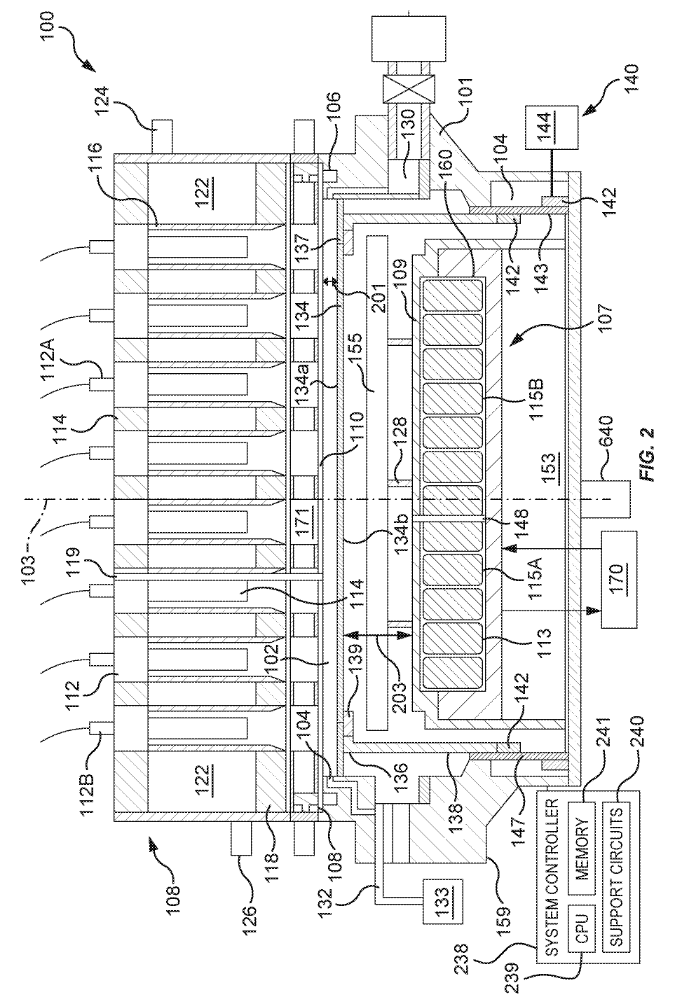

One or more magnets 142 are mounted on lift ring 138. The magnetic fields of magnets 142 extend through the chamber walls 104 and couple to magnets 142 mounted on a drive ring 143, which is suitably driven. Rotation of the lift ring 138 enables the lift ring 138, to rotate the substrate support 136, the support ring 139, and the substrate 134. The magnetic coupling eliminates the need for an elaborate vacuum-sealed drive assembly. The magnetic lift mechanism 140 translates the substrate support 136, the support ring 139, and the substrate 134 toward the preheat ring 137 from below a slit valve 155 to above the slit valve 155 when the processing chamber 100 changes position. In some embodiments, the magnetic lift mechanism 140 translates the substrate support 136, the support ring 139, and the substrate 134 at least 50 millimeters or more from a transfer position to a processing position (FIG. 2).

The bottom window 109 includes support pins 128. For example, the support pins 128 are the same material as the bottom window. The support pins 128 extend from the bottom window 109 toward the processing region 102. The substrate 134 enters the processing region 102 through a slit valve 155 and is disposed on pins tips of each of the support pins 128. The slit valve 155 is an aperture formed through the chamber walls 104. The slit valve 155 enables the substrate 134 to be transferred in and out of the processing chamber 100.

The processing chamber 100 is configured to deposit a silicon film or silicon film doped with carbon on the substrate 134. The source gases enter the processing region 102 from an inlet 130. The source gases may include a silicon source gas, a carbon source gas, an additive gas, or any other suitable gas. A vacuum pump 133 may be fluidly connected to the processing region 102 through an outlet 132 for pumping out effluent gases. In some embodiments, the vacuum pump 133 is a turbo pump configured to enable the fast gas exchange between when processing chamber 100 deposits a silicon (Si) film and the processing chamber 100 deposits a silicon germanium (SiGe) film to form multi-layer stacks.

In some embodiments, the upper lamp module 108 includes a plurality of top pyrometers 119. The top pyrometers 119 may be disposed above the top window 110 and substrate 134. The top pyrometers 119 measure the temperatures at a topside of the substrate 134. In some embodiments, each top pyrometer 119 is surrounded by the top lamps 112.

Each lamp of the plurality of top lamps 112 may include a light pipe 114 with a lamp mounted therein. The light pipe 114 may be constructed of stainless steel, brass, aluminum, or other metals. The ends of the light pipes 114 are secured to chamber walls 116, 118 of the upper lamp module 108. The chamber walls 116, 118 may be brazed, welded, or otherwise secured to the peripheral edge of the chamber walls 116, 118. The chamber walls 116 define a cooling chamber 122 of the upper lamp module 108.

A coolant is introduced into the cooling chamber 122 via a top environment control system 124 and is removed at an outlet 126. The coolant travels in the space between the light pipes 114, thereby cooling them. The coolant may be a liquid or a gas. The top environment control system 124 enables control of the temperature and pressure of the upper lamp module 108 so that the top window 110 is kept at a controlled temperature and a pressure differential between the processing region 102 and a cavity 171 within the upper lamp module 108 can be monitored and maintained.

The bottom lamp module 107 is disposed below (backside) the substrate 134. In some embodiments, a plurality of lower pyrometers 148 may be disposed in the bottom lamp module 107 and below the substrate 134 and the substrate support 136. The plurality of lower pyrometers 148 are configured to measure temperatures at a backside of the substrate 134. In some embodiments, at least one of the plurality of lower pyrometers 148 is surrounded by the bottom lamps 113.

A protective region 153 is formed within the bottom lamp module 107. The processing region 102 and the protective region 153 may have different environments, such as different gases, different gas pressures, and different temperatures. In some embodiments, the pressure of the protective region 153 is higher than the processing region 102. The protective region 153 is separated from the processing region 102 by the bottom window 109.

In some embodiments, the bottom window 109 includes a thickness about equal to a thickness of the top window 110. In some embodiments, the bottom window 109 and the top window 110 are quartz windows. The top environment control system 124 and the cooling system 170 are configured to control the temperature and pressure differential experienced by the top window 110 and the bottom window 109, respectively.

The processing chamber 100 includes the controller 238 coupled with other components of the processing chamber 100 and configured to operate the various components and processing operations of the processing chamber 100. The controller 238 generally includes one or more processors 239, memory 241, and support circuits 240. The one or more processors 239 may include a central processing unit (CPU) and may be one of any form of a general-purpose processor that can be used in an industrial setting. The controller 238 is communicatively coupled to the top environment control system 124 and the cooling system 170. The memory 241 includes instructions that, when executed by one or more processors cause one or more operations to be conducted, the one or more operations include at least one of maintaining a temperature and pressure within the bottom lamp module 107 and the upper lamp module 108. The CPU can cause one or more operations to be conducted, the one or more operations comprise at least one of determining if a pressure differential exists between the processing region 102 compared to inside the bottom lamp module 107 or the upper lamp module 108, determining a temperature of the substrate 134, and determining a flow rate and pressure of processing gas through the inlet 130.

The memory 241, or non-transitory computer-readable medium, is accessible by the one or more processors 239 and may be one or more of memory such as random access memory (RAM), read only memory (ROM), floppy disk, hard disk, or any other form of digital storage, local or remote. The support circuits 240 are coupled to the one or more processors 239 and may comprise cache, clock circuits, input/output subsystems, power supplies, and the like. The various methods disclosed herein may generally be implemented under the control of the one or more processors by the one or more processors executing computer instruction code stored in the memory as, for example, a software routine. When the computer instruction code is executed by the one or more processors 239, the one or more processors 239 controls the processing chamber 100 to perform processes in accordance with the various methods disclosed herein.

FIG. 2 illustrates a schematic cross-sectional view of the processing chamber 100 in a processing position, according to one or more embodiments.

The processing chamber 100 is in the processing position when the substrate support 136 has raised the substrate 134 off the support pins 128. For example, the substrate support 136 lifts the substrate 134 off the support pins 128 and translates the substrate 134 toward the preheat ring 137. The magnetic lift mechanism 140 translates the substrate 134 and the substrate support 136 above the slit valve 155.

In some embodiments, the magnetic lift mechanism 140 is configured to translate the substrate 134 and the substrate support 136 about 4 inches or more when the processing chamber 100 changes from the transfer position to the processing position. In some embodiments, the magnetic lift mechanism 140 disposes the substrate 134 within 20 millimeters or less of the top window 110 during processing. For example, the magnetic lift mechanism 140 disposes the substrate 134 at 16 millimeters or less from the top window 110 during processing. In another example, the magnetic lift mechanism 140 disposes the substrate 134 about 5 millimeters to about 30 millimeters away from the top window 110 during processing. The proximity of the substrate 134 to the top window 110 enables enhanced temperature control of the processing region 102 and the substrate 134. Disposing the substrate 134 closer to the top window 110 reduces the volume of the processing region 102 allowing for a reduction in required processing gas.

The substrate 134 includes a first substrate surface 134a and a second substrate surface 134b opposite the first substrate surface 134a. The first substrate surface 134a faces the upper lamp module 108 and receives energy from the top lamps 112. The second substrate surface 134b faces the bottom lamp module 107 and receives energy from the bottom lamps 113.

The substrate support 136 is disposed a first distance 201 from the upper lamp module 108 when in the processing position. In some embodiments, the first distance 201 disposes the substrate support 136 and the substrate 134 about 10 millimeters to about 60 millimeters from the upper lamp module 108 when in the processing position. In some embodiments, the substrate support 136 and the substrate 134 are disposed about 5 millimeters to about 120 millimeters from the upper lamp module 108 when in the processing position. When in the processing position, the substrate support 136 is disposed a second distance 203, from the bottom lamp module 107. In some embodiments, the difference between the first distance 201 and the second distance 203 is a stroke of the substrate support 136. In some embodiments, a ratio between the first distance 201 and the second distance 203 is at least 1:2 in the processing position and the ratio is at least 2:1 in a transfer position. In some embodiments, a ratio between the first distance 201 and the second distance 203 is at least 1:1 in the processing position and the ratio is at least 1:1 in a transfer position.

When the substrate support 136 is disposed in a transfer position, the substrate support 136 and the substrate 134 are disposed about 30 millimeters to about 300 millimeters from the upper lamp module 108.

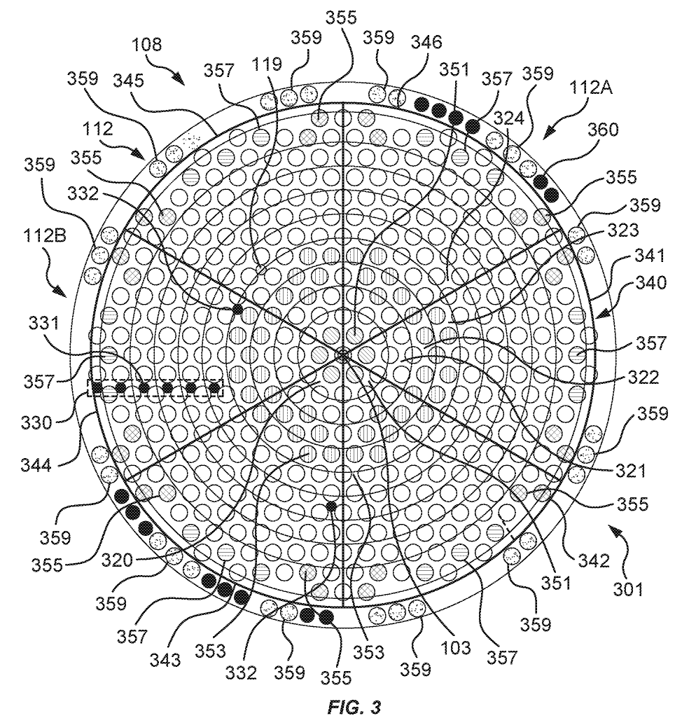

FIG. 3 illustrates a schematic top view of the upper lamp module 108, according to one or more embodiments.

As shown, the first top plurality of lamps 112A of the top lamps 112 are organized into groups. Each lamp of the first top plurality of lamps 112A may be in multiple groups of lamps. The groupings of lamps may be organized by geometry formed by the chosen lamps and defined by their location within the upper lamp module 108. In another example, a lamp may be part of one or more groups and depends on the geometry of the desired heating profile. For example, the first plurality of groups 301 includes a center group 320, a first group 321, a second group 322, a third group 323, and a fourth group 324. Thus, the first plurality of groups 301 includes the center group 320 and concentric groupings of lamps around the center group 320. That is, the first group 321 is concentric to the center group 320 and the second group 322 is radially outward and concentric with the first group 321.

The second top plurality of lamps 112B are distributed azimuthally. In some embodiments, the second top plurality of lamps 112B includes one or more zone tuning lamps 331 and are part of a second plurality of groups 330. In some embodiments, the second top plurality of lamps 112B further includes one or more spot tuning lamps 332. In some embodiments, the top lamps 112 of the upper lamp module 108 further include a third plurality of groups 340. The third plurality of groups 340 divide the lamps between the first wedge group 341, a second wedge group 342, a third wedge group 343, a fourth wedge group 344, a fifth wedge group 345 and a sixth wedge group 346. The third plurality of groups 340 may include all of the top lamps 112. The first plurality of groups 301, the second plurality of groups 330, the spot tuning lamps 332, and the third plurality of groups 340 enable the processing chamber 100 (FIGS. 1 and 2) to account for the cross flow of processing fluid traveling from the inlet 130 (FIG. 1) to the outlet 132 (FIG. 1). The first plurality of groups 301, the second plurality of groups 330, the spot tuning lamps 332, and the third plurality of groups 340 further enable the formation of tunable heat application profiles to apply thermal energy to the substrate 134 (FIG. 1).

In some embodiments, the top lamps 112 include a first group of lamps 351, a second group of lamps 353, a third group of lamps 355, a fourth group of lamps 357, and a fifth group of lamps 359.

The first group of lamps 351 may be disposed centrally within the upper lamp module 108. The second group of lamps 353 forms a ring surrounding the first group of lamps 351. In some embodiments, the second group of lamps 353 form a continuous ring around the first group of lamps 351. For example, each lamp of the second group of lamps 353 is adjacent to another lamp of the second group of lamps 353.

The third group of lamps 355 is disposed concentrically with the first group of lamps 351 and the second group of lamps 353. In some embodiments, the third group of lamps 355 is disposed radially outward of the first group of lamps 351 and the second group of lamps 353. The third group of lamps 355 includes separated subgroups arranged at equal angular intervals. In some embodiments, separated subgroups include subgroups with one or more lamps between the concentric subgroups. In other words, lamps from other groups are disposed between the subgroups of the third group of lamps 355. In some embodiments, the subgroups are disposed at a diameter similar to the diameter of the substrate 134. In some embodiments, each subgroup is arranged with a symmetric number of lamps in relation to the angular interval.

In the embodiment shown, the fourth group of lamps 357 is concentric with the first group of lamps 351 and the second group of lamps 353. In some embodiments, the fourth group of lamps 357 is disposed radially outward of the first group of lamps 351 and the second group of lamps 353. In some embodiments, the fourth group of lamps 357 is disposed at about the same radial distance from the center as the third group of lamps 355. The fourth group of lamps 357 includes subgroups disposed between the subgroups of the third group of lamps 355. In some embodiments, the fourth group of lamps 357 form linear arrays at equal angular offsets, for example, 60 degrees from a vector formed of an adjacent subgroup of the fourth group of lamps 357. While illustrated as perpendicular to a vector from the center of the top lamps 112, each subgroup of the fourth group of lamps 357 may be arranged in a linear array at an offset angle relative to a vector from the center of the top lamps 112 to the respective subgroup.

In the embodiment shown, the fifth group of lamps 359 is concentric with the first group of lamps 351, the second group of lamps 353, the third group of lamps 355, and the fourth group of lamps 357. In some embodiments, the fifth group of lamps 359 is disposed radially outward of the first group of lamps 351 and the second group of lamps 353. In some embodiments, the fifth group of lamps 359 is disposed radially outward of the first group of lamps 351, the second group of lamps 353, the third group of lamps 355, and the fourth group of lamps 357. The fifth group of lamps 359 includes subgroups arranged at equal angular intervals. In some embodiments, the subgroups include an alternating number of lamps. For example, the fifth group of lamps 359 has alternating subgroups of two and three lamps. In some embodiments, each subgroup of the fifth group of lamps 359 is separated from the other subgroups by lamps of another group.

The arrangements of the lamp groups 351, 353, 355, 357, 359 shown in FIG. 3 and described above are exemplary and do not preclude other arrangements. For example, the second group of lamps 353 may be radially outward of the fifth group of lamps 359.

In the embodiment shown, the top lamps 112 include a sixth group of lamps 360. The sixth group of lamps 360 are distributed over the preheat ring 137 and are aligned with the inlet 130 and the outlet 132 (FIG. 1). The sixth group of lamps 360 are distributed in opposing quadrants and counteract cooling caused by vortex type gas flows created as gas flows through the inlet 130 and the outlet 132. For example, the sixth group of lamps 360 are configured to apply thermal energy to a portion of the preheat ring 137 adjacent to the inlet 130 (FIG. 1) of the processing chamber 100 with a third group of lamps.

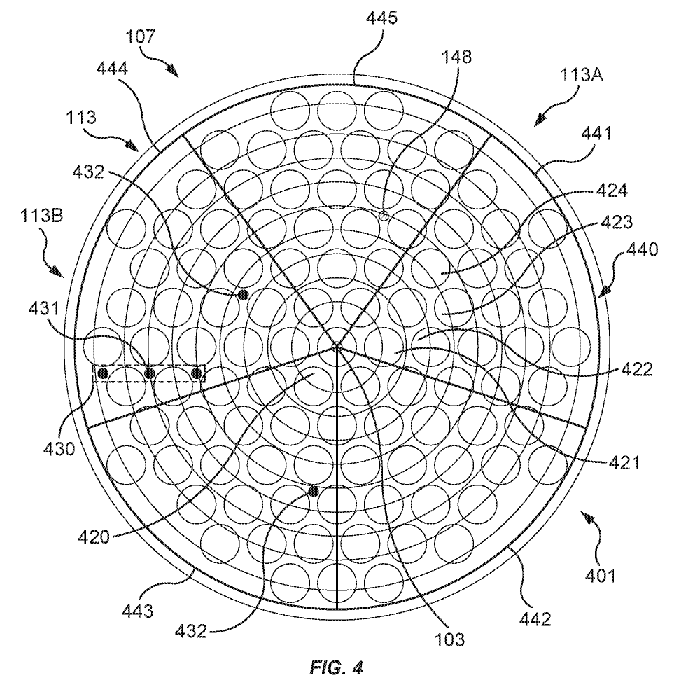

FIG. 4 illustrates a schematic top view of the bottom lamp module 107, according to one or more embodiments.

As shown, the first bottom plurality of lamps 113A of the bottom lamps 113 are disposed in a first plurality of zones 401. For example, the first plurality of zones 401 includes a center zone 420, a first zone 421, a second zone 422, a third zone 423, and a fourth zone 424. The first plurality of zones 401 includes the center zone 420 and concentric zones around the center zone 420. For example, the first zone 421 is concentric to the center zone 420 and the second zone 422 is radially outward and concentric with the first zone 421.

The second bottom plurality of lamps 113B is distributed azimuthally between the first plurality of bottom lamps 113A. In some embodiments, the second bottom plurality of lamps 113B includes one or more zone tuning lamps 431 within a second plurality of zones 430. In some embodiments, the second bottom plurality of lamps 113B further includes one or more spot tuning lamps 432. In some embodiments, the bottom lamps 113 of the bottom lamp module 107 further includes a third plurality of zones 440. The third plurality of zones 440 includes a first wedge zone 441, second wedge zone 442, a third wedge zone 443, a fourth wedge zone 444, and a fifth wedge zone 445. The third plurality of zones 440 may include all of the bottom lamps 113. The first plurality of zones 401, the second plurality of zones 430, the spot tuning lamps 432, and the third plurality of zones 440 enable the processing chamber 100 (FIGS. 1 and 2) to account for the cross flow of processing fluid traveling from the inlet 130 (FIG. 1) to the outlet 132 (FIG. 1). In some embodiments, the bottom lamps 113 provide over half of the total energy to the substrate 134 and the top lamps 112 are able to form tunable heat application patterns on the substrate 134 (FIG. 1).

Referring to FIGS. 3 and 4, the top lamps 112 and the bottom lamps 113 each includes a number of lamps per unit area. In some embodiments, the number of lamps per unit area of the top lamps 112 is about equal to the number of lamps per unit area of the bottom lamps 113. In some embodiments, the upper lamp module 108 includes more lamps than the bottom lamp module 107. In addition to a radial pattern, the top lamps 112 may be arranged in, a hexagonal pattern, cubic pattern, a diamond pattern, a triangular pattern, or a combination thereof. By arranging the top lamps 112 in a non-radial pattern, lamp density can be increased, thereby enabling an increase in process configuration options for dynamic heating processes and applications.

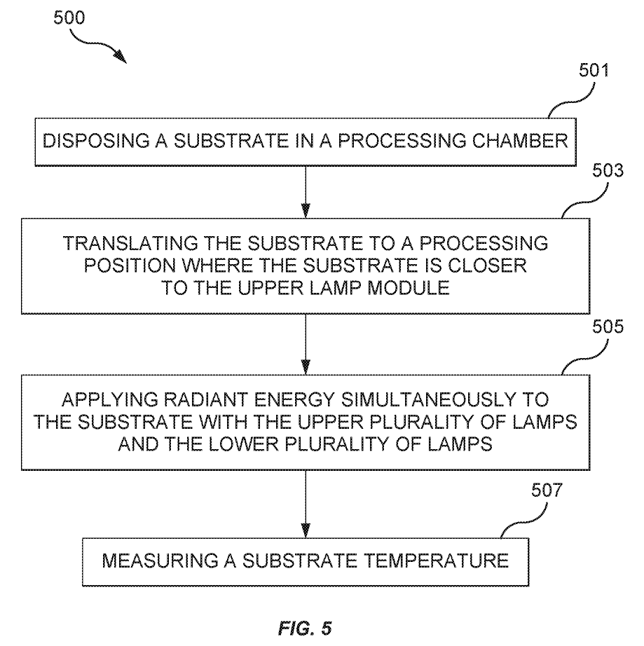

FIG. 5 illustrates a flow diagram of a method 500, according to one or more embodiments. The method 500 is discussed with reference to FIGS. 1, 2, 3, and 4.

At operation 501, the substrate 134 is disposed in the processing chamber 100 during a transfer operation. The substrate 134 enters the processing region 102 through the slit valve 155 and is disposed on pin tips of the support pins 128. The pin tips are the distal ends of each of the support pins 128. As shown in FIG. 1, the substrate 134 is disposed on the substrate support 136 when the processing chamber 100 is in the transfer position. The substrate 134 is disposed between the upper lamp module 108 and the bottom lamp module 107.

At operation 503, the substrate 134 is translated from the transfer position to the processing position, as shown in FIG. 2. When the processing chamber 100 is in the processing position, the substrate 134 is closer to the upper lamp module 108 than to the bottom lamp module 107. The substrate support 136 translates the substrate 134 from the support pins 128 toward the preheat ring 137.

In some embodiments, the substrate support 136 is a support ring that lifts the substrate 134 off of the support pins 128 of the bottom window 109 and translates the substrate 134 toward the preheat ring 137.

At operation 505, the plurality of top lamps 112 and the plurality of bottom lamps 113 simultaneously apply radiant energy to the substrate 134. For example, the plurality of top lamps 112 apply a first energy to the first substrate surface 134a and the plurality of bottom lamps 113 apply a second energy to the second substrate surface 134b. In some embodiments, the second energy is double the first energy. For example, the plurality of top lamps 112 apply less than half the thermal energy to the substrate 134 compared to the plurality of bottom lamps 113. In some embodiments, the plurality of top lamps 112 preheat the substrate 134, the preheat ring 137, and/or the substrate support 136 prior to a semiconductor processing operation. In some embodiments, the substrate 134 is rotated about the central axis 103 when the energy is being applied.

In some embodiments, the plurality of bottom lamps 113 apply a bulk amount of energy for general substrate heating and the plurality of top lamps 112 are used to tune the temperature profile of energy applied to the substrate 134. This distinction enables the substrate 134 to have a uniform temperature profile across the first substrate surface 134a and the second substrate surface 134b. For example, the plurality of top lamps 112 apply energy to the substrate 134 in an azimuthal pattern to compensate for components, rotation, and flow rates within the processing chamber.

At operation 507, one or more of the top pyrometers 119 measures the temperature of the first substrate surface 134a and one or more of the lower pyrometers 148 measures the temperature of the second substrate surface 134b. Measuring the first substrate surface 134a and the second substrate surface 134b occurs simultaneously with applying the radiant energy and enables a real-time in-situ temperature measurement.

Either or both of operation 505 and operation 507 may include a deposition process, an etch process, an anneal process, or any combination thereof.

As described herein, the implementation of a turbo pump as a vacuum pump 133 (FIG. 1) and the high density the bottom lamp module 107 enable higher precision deposition for depositing layers during the manufacture of three‑dimensional dynamic random‑access memory (3D DRAM), complementary field-effect transistor (cFET), and gate-all-around (GAA) devices.

During manufacture of the above described devices, processing chambers may alternate between deposition temperatures required for layers within a layer stack. For example, a first layer is deposited at a first temperature of about 620 degrees Celsius to about 660 degrees Celsius and then the processing chamber must heat to a second temperature of about 700 degrees Celsius to 740 degrees Celsius to deposit the second layer. The processing chambers, apparatus, and systems described herein enable the change in temperature from the first temperature to the second temperature in 20 seconds or less, for example about 10 seconds or less. The processing chambers, apparatus, and systems described herein also enable consistent temperature uniformity during the temperature changes.

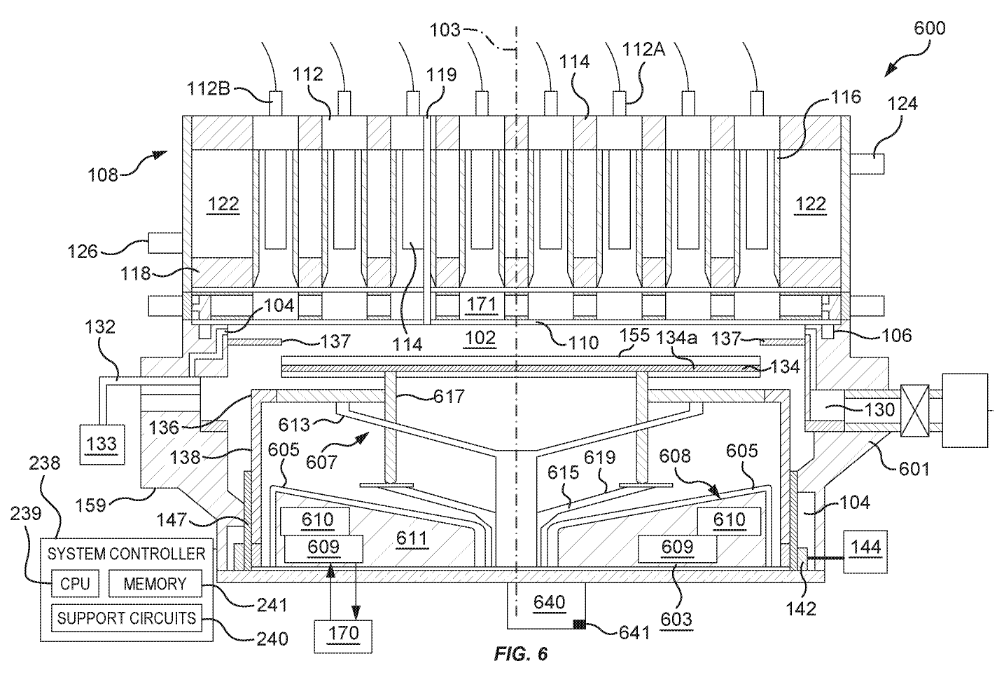

FIG. 6 illustrates a schematic cross-sectional view of a processing chamber 600, in a transfer position according to one or more embodiments.

The processing chamber 600 includes a chamber body 601 that defines the processing region 102, the central axis 103, the upper lamp module 108, and a bottom lamp module 603. The processing chamber 600 can be a reduced-pressure or vacuum chamber. The chamber body 601 at least partially defines the processing region 102.

In some embodiments, the processing chamber 600 functions as an epitaxy deposition chamber configured to deposit one or more layers of materials on a substrate 134. In some embodiments, the processing chamber 600 functions as a rapid thermal processing (RTP) chamber. The upper lamp module 108 is described above in relation to FIGS. 1 and 2.

The bottom lamp module 603 is disposed on a bottom side of the chamber body 601. The bottom lamp module 603 is separated from the processing region 102 by a bottom window 605. The bottom lamp module 603 includes a plurality of bottom lamps.

The plurality of bottom lamps include inner lamps 609 and outer lamps 610. The plurality of bottom lamps may be UV lamps, halogen lamps, laser diodes, resistive heaters, microwave powered heaters, light emitting diodes (LEDs), or any other suitable heating elements both singly or in combination. The plurality of bottom lamps may be disposed in a lamp cavity 611 formed in the bottom lamp module 603. Each plurality of lamps may be controlled independently by the controller 238 to provide desired temperature profile across the substrate 134.

In some embodiments, the bottom lamp module 603 is coupled to the cooling system 170. The cooling system 170 is configured to maintain a temperature of the bottom window 605.

The processing chamber 600 further includes a substrate support 607 that is configured to support the substrate 134. The substrate support 607 can translate the substrate 134 within the processing region 102. In some embodiments, the substrate support 607 is a support ring that supports the substrate 134 at a radially outward edge of the substrate 134. The substrate support 607 includes a plurality of support arms 613 and a substrate lift 615. The substrate lift 615 contacts the lift pins 617 to raise the substrate from the plurality of support arms 613. In some embodiments, the plurality of support arms 613 include six support arms 613 and the substrate lift 615 includes three lift pin arms 619 aligned with alternating support arms 613. For example, there is a lift pin arm 619 coupled to every other support arm 613.

The support arms 613 cause localized temperature increases on the substrate 134 but the lift pin arms 619 prevent the same amount of heat being transmitted to the substrate 134. This creates localized higher temperature areas on the portions of the substrate where the substrate 134 is supported by the support arms 613 without corresponding lift pin arms 619 and localized lower temperature areas on the portions of the substrate where the substrate 134 is supported by the support arms 613 with corresponding lift pin arms 619.

In some embodiments, the above described heat distribution creates a heat distribution on the substrate with alternating high and low temperature spokes. When using radial heating groups, e.g., a heating zone in the shape of a ring that evenly applies energy across the surface of the substrate, radial heating alone cannot address the above described temperature irregularity as the substrate rotates during a processing operation.

The controller 238 includes instructions or a recipe in the memory 241 that when executed by the controller 238 cause specific top lamps 112 to activate and apply energy in circular heating sectors that track the lower temperature regions of the substrate 134 above the lift pin arms 619 as the substrate support 607 rotates during processing. In other words, the controller 238 enables a rotating power distribution of energy from the top lamps 112 that heats the substrate 134. For example, when the substrate 134 is rotated at 60 rpm or less, the controller 238 provides instructions to the top lamps 112 to increase energy applied to the corresponding group of the third plurality of groups 40 (FIG. 3) disposed over corresponding lift pin arms 619.

The substrate support 607 is coupled to a lift mechanism 640. The lift mechanism 640 is coupled to the chamber walls 104 of the chamber body 601 and the substrate lift 615. The lift mechanism 640 includes an encoder 641 coupled to the substrate lift 615 and in communication with the controller 238 (FIG. 2). The encoder 641 enables the controller 238 to detect the angular position of the substrate support 607 as it rotates. The lift mechanism 640 includes an actuator configured to raise and lower the substrate support 607 with respect to the top window 110 and rotate the substrate support 607.

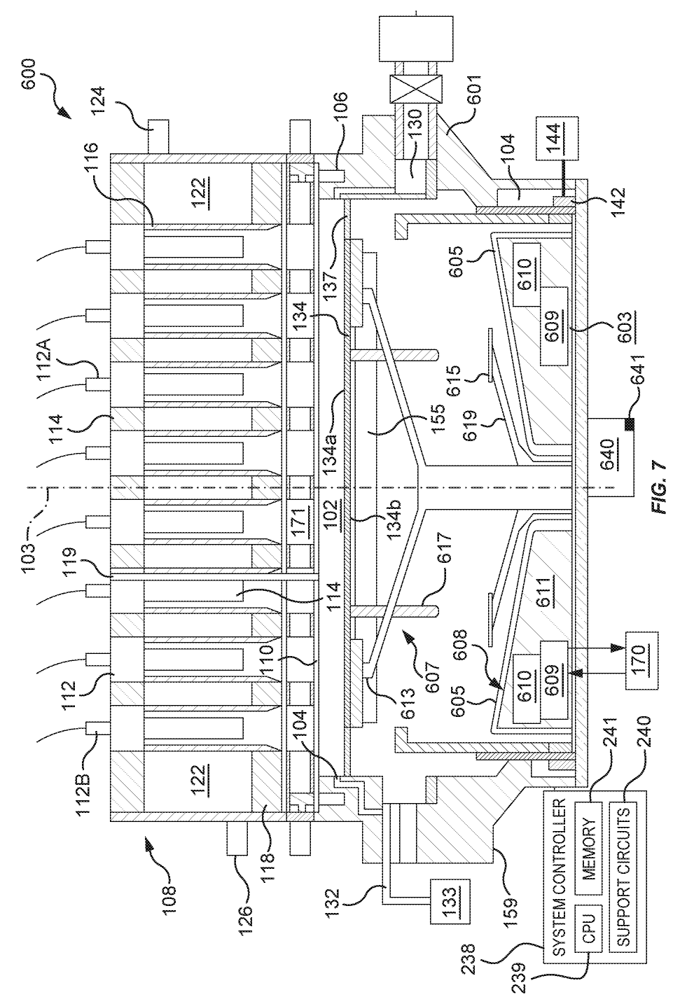

The lift mechanism 640 translates the substrate support 607 and the substrate 134 toward the preheat ring 137 from a transfer position below the slit valve 155 to a processing position above the slit valve 155. In some embodiments, the lift mechanism 640 translates the substrate support 607 and the substrate 134 at least 50 millimeters or more from the transfer position to the processing position (FIG. 7)

FIG. 7 illustrates a schematic cross-sectional view of the processing chamber 600 in a processing position, according to one or more embodiments.

The processing chamber 600 is in the processing position when the substrate support 607 has raised the substrate 134 off the lift pins 617. The substrate support 607 lifts the substrate 134 off the lift pins 617 and translates the substrate 134 toward the preheat ring 137. The lift mechanism 640 translates the substrate 134 and the substrate support 607 above the slit valve 155. The lift mechanism 640 is configured to translate the substrate 134 and the substrate support 607 about 4 inches or more when the processing chamber 600 changes from the transfer position to the processing position. The lift mechanism 640 disposes the substrate 134 within 20 millimeters of the top window 110 during processing. For example, the lift mechanism 640 disposes the substrate 134 at 16 millimeters or less from the top window 110 during processing. In another example, the lift mechanism 640 disposes the substrate 134 12 millimeters away from the top window 110 during processing. The proximity of the substrate 134 to the top window 110 enables enhanced temperature control of the processing region 102 and the substrate 134. Disposing the substrate 134 closer to the top window 110 reduces the volume of the processing region 102 allowing for a reduction in required processing gas.

In one embodiment, the processing chamber 600 is configured to deposit a SiC film on the substrate 134 when the substrate 134 is in the processing position as shown in FIG. 7. The source gases enter the processing region 102 from the inlet 130. The vacuum pump 133 may be fluidly connected to the processing region 102 through the outlet 132 for pumping out effluent gases. The bottom lamp module 603 is disposed below (backside) the substrate 134. In some embodiments, the bottom window 605 includes a thickness about equal to a thickness of the top window 110.

For example, the substrate 134 includes a first substrate surface 134a and a second substrate surface 134b opposite the first substrate surface 134a. The first substrate surface 134a faces the upper lamp module 108 and receives energy from the top lamps 112. The second substrate surface 134b faces the bottom lamp module 603 and receives energy from the bottom lamps 608.

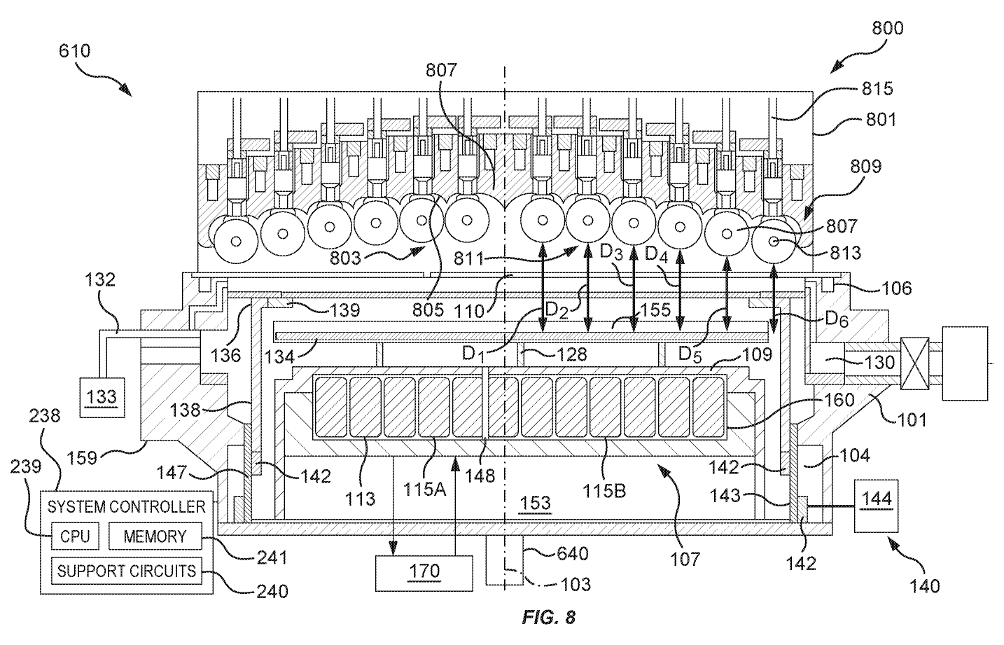

FIG. 8 illustrates a schematic cross-sectional view of a processing chamber 800 in a processing position, according to one or more embodiments.

The processing chamber 800 includes an upper lamp module 801. The upper lamp module 801 is intended for precision heating of a semi-conductor substrate 134 in a high temperature environment to maintain uniformity layers deposited on the substrate 134. The upper lamp module 801 further includes the top window 110 and a reflector array 803. The reflector array 803 includes a plurality of concentric reflector rings 805 facing downwardly towards the substrate support 136. Each concentric reflector ring 805 includes a circular heat lamp array 807 located in end-to-end relation to completely fill each reflector ring. Each circular heat lamp array 807 is oriented with its longitudinal axis in the circumferential direction of the respective reflector ring 805, and its transverse axis in the radial direction of the circular reflector array heated by the upper lamp module 801.

As shown in FIG. 8, the upper lamp module 801 comprises six concentric rings 809 disposed around the central axis 103. In some embodiments, the upper lamp module 801 includes a plurality of concentric rings 809, which each include a circular heat lamp array 807 that includes a plurality of lamps of any configuration (e.g., bulbs, linear shaped lamps, etc.). Each circular heat lamp array 807 includes tunable horizontal filament spot lamps 811. Each heat lamp in a circular heat lamp array 807 comprises a filament 813 that is mechanically and electrically connected to a pair of filament posts 815. The electrical power supplied to each ring and to each lamp is controlled individually. An electrical power control circuit provides the necessary control circuitry to provide independent control of each concentric ring.

In one or more embodiments, the spacing between each concentric ring 809 (e.g., D₁, D₂, D₃, D₄, D₅, and D₆) is adjustable along the central axis 103 relative to the substrate 134. In such embodiments, each concentric ring 809 can be positioned at a specific height to compensate for temperature non-uniformity across the substrate surface. By varying the vertical spacing along the central axis 103 relative to the substrate 134 (e.g., D₁, D₂, D₃, D₄, D₅, and D₆), the radiant flux distribution from each circular heat lamp array 807 can be tailored to address localized thermal gradients caused by edge effects, material thickness variations, or process-induced asymmetries. In some embodiments, the spacing adjustments along the central axis 103 are determined through thermal modeling or real-time feedback from temperature sensors, ensuring uniform heat transfer and minimizing thermal stress during processing. Such flexibility in the positioning of concentric rings 809 and their corresponding individual circular heat lamp array 807 enhances process consistency, improves substrate quality, and reduces the risk of defects associated with uneven heating.

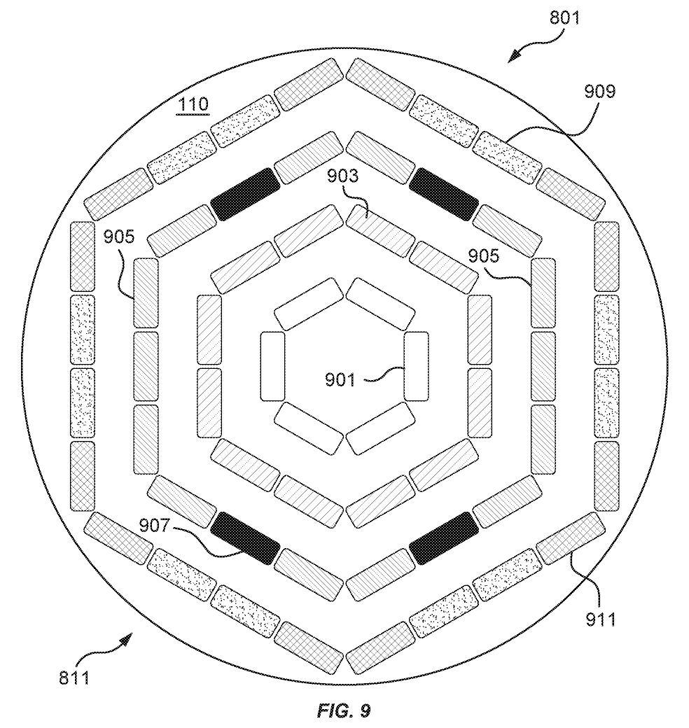

In other embodiments, the upper lamp module 801 comprises a plurality of top lamps having structural and geometric configurations different from those of the upper lamp module 801. In such embodiments, for example, the upper lamp module 801 comprises the top lamps 112 shown in FIG. 1. As mentioned above with respect to FIG. 1, the top lamps 112 are disposed parallel to the central axis 103. As described above for the concentric rings 809, the vertical distance between the top lamps 112 (shown in FIG. 1) and the substrate 134 can also be adjusted to optimize thermal uniformity. FIG. 9 illustrates a schematic top view of the upper lamp module 801, according to one or more embodiments.

As shown, the spot lamps 811 include a first lamp set 901, a second lamp set 903, a third lamp set 905, a fourth lamp set 907, a fifth lamp set 909, and a sixth lamp set 911. While shown as six lamp sets, the upper lamp module 801 may include over six lamp sets in multiple interspersed patterns. For example, the upper lamp module 801 may include fifteen tunable lamps sets with actuatable individual lamps in each set. The lamp sets are arranged in a hexagonal pattern above the top window 110. While shown as horizontal filament lamps, the spot lamps 811 may also be the plurality of top lamps 112 (FIG. 3) arranged in a hexagonal pattern to form a tunable upper lamp module 801. The lamp sets can be arranged in various patterns. For example, the first lamp set 901 is disposed radially inward of the a second lamp set 903 and the fourth lamp set 907 disrupts the hexagonal ring pattern of the third lamp set 905. In some embodiments, the fifth lamp set 909 and the sixth lamp set 911 are disposed around two or more lamp sets.

In some embodiments, the spot lamps 811 include a radial pattern where the first lamp set 901 includes a first portion of the spot lamps 811 disposed in a ring pattern and the second lamp set 903 includes a second portion of the spot lamps 811 arranged in a second ring disposed around and concentric with the first lamp set 901. In some embodiments, the power supplied to the spot lamps 811 is alternated to correspond to rotation of the substrate 134 and the support arms 613 (FIG. 6). For example, as the support arms 613 are rotated below the fifth lamp set 909, power supplied to the fifth lamp set 909 is increased until the support arms 613 are rotated below the sixth lamp set 911, at which time power supplied to the fifth lamp set 909 is decreased and power supplied to the sixth lamp set 911 is increased. In some embodiments, the fifth lamp set 909 is azimuthally and concentrically distributed in relation to the sixth lamp set 911. The term lamp set and lamp group may be interchanged as described herein.

In some embodiments, the spot lamps 811 are distributed azimuthally. The spot lamps 811 include various set patterns to enable the processing chamber 800 (FIG. 8) to account for the cross flow of processing fluid traveling from the inlet 130 (FIG. 1) to the outlet 132 (FIG. 1) and form tunable heat application patterns on the substrate 134 (FIG. 8).

A benefit of configuring the individual heat lamps in concentric rings is that a homogenous angular energy distribution can be achieved. In addition, each radial group can be controlled with a high degree of precision. In some embodiments, the lamp radial distribution is not aligned symmetrically and has an angular shift between each ring in order to improve energy uniformity for all angular or radial directions. For example, the heat lamps in each reflector ring 805 are in a staggered relation with respect to those in the adjacent rings such that most of the heat lamps in each ring are not in radial alignment with the heat lamps in the adjacent rings.

In some embodiments, the concentric rings 809 are disposed in a gradual upward sloping arc from the outer edge to the center of the heater. In some embodiments, the concentric rings 809 are disposed in in a flat plane.

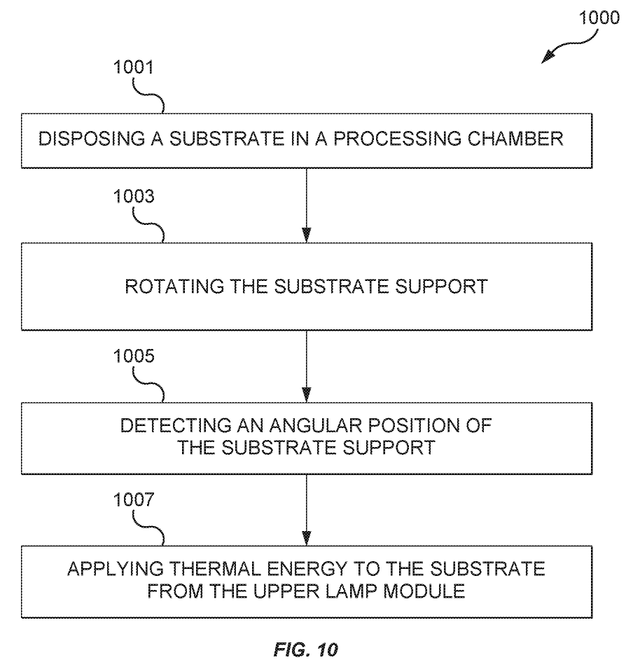

FIG. 10 illustrates a flow diagram of a method 1000, according to one or more embodiments. The method 1000 will be described in reference to FIGS. 3, 6, and 7, but is not limited to those Figures.

At operation 1001, the substrate 134 is disposed on a substrate support in a processing chamber. For example, the substrate 134 is disposed on the substrate support 607 of the processing chamber 600 shown in FIGS. 6 and 7. As noted above the processing chamber 600 includes the support arms 613 and plurality of lift pins 617.

At operation 1003, the substrate support 607 rotates the substrate 134 about the central axis 103 based on instructions from the controller 238. As the substrate support 607 rotates, the support arms 613 and plurality of lift pins 617 are also rotated.

At operation 1005, the angular position of the substrate support 607 is detected. For example, the controller 238 determines the angular position of the substrate support 607 based on signals transmitted from the encoder 641 of the substrate lift 615.

At operation 1007, thermal energy is applied to the substrate 134 from the upper lamp module 108 by the top lamps 112 and the bottom lamps 608 of the bottom lamp module 603 based, at least in part, on the angular position determined by the controller 238. For example, the controller 238 causes the upper lamp module 108 and the bottom lamp module 603 to apply heat the substrate based on the determined angular position of the substrate 134. The top lamps 112 of the upper lamp module 108 are disposed opposite the plurality of lift pins 617 from the substrate 134 and provide enhanced tuning of the applied thermal energy. The total thermal energy is the thermal energy applied to the substrate 134 by the top lamps 112 and the bottom lamps 608. The total thermal energy may stay the same while thermal energy from individual lamp groups changes.

The thermal energy applied by one or more groups of lamps is varied in relation to an angular position of the substrate support 607 to account for interference caused by the thermal energy reflected by at least the plurality of lift pins 617 and the support arm 613. The support arm 613 and the lift pins 617 reduce the amount of thermal energy from the bottom lamp module 603 able to reach the portions of the substrate 134 above the support arm 613 and the lift pins 617. The reduction in thermal energy transmission causes temperature non-uniformity resulting in lower temperature regions of the substrate 134 above the support arm 613 and the lift pins 617 and higher temperatures regions of the substrate 134 between the support arm 613 and the lift pins 617. Further, the rotation of the substrate support 607 causes translation of the angular positions of the lower temperature regions of the substrate 134 that correspond to the rotations per minute (RPM) of the substrate support 607. The detected angular position of the substrate support 607 enables the controller 238 to determine and vary the amount of power applied to certain lamp groups to apply more thermal energy to the lower temperatures regions as the substrate 134 rotates. For example, the controller 238 is able to vary the power to a group of lamps with separated subgroups so that the additional thermal energy applied is selective to the lower temperature regions of the substrate 134. In contrast, a continuous ring of lamps would supply additional thermal energy to the lower temperatures regions and the higher temperature regions. The encoder 641 and lamp groupings arranged in separated subgroups enables the controller 238 to tune the amount of thermal energy applied to the substrate 134 in relation to the angular position and/or RPM of the substrate support 607. The controller 238 tracks increases power to the lamp groups in relationship relative to the lower temperature regions of the substrate 134 enabling enhanced temperature uniformity azimuthally and radially across the substrate 134, even during rotation.

In some embodiments, the method 1000 includes the controller 238 applying an initial power level to the top lamps 112, which corresponds to applying a base thermal energy to the substrate 134 and then pulsing power increases to one or more lamp groups. Pulsing power increases includes increasing the power supplied to one or more lamp groups in relation to the RPM of the substrate support 607. For example, pulsing power increases includes varying the power supplied to one or more lamp groups in relation to the angular position of the support arm 613 and/or the lift pins 617 as the substrate support 607 rotates. Varying the power includes increasing the power to one or more groups of lamps from the initial amount applied to a second power level greater than the initial power level and then reducing the power to the one or more groups of lamps back to the first power level in relation to the RPM of the substrate support 607.

The varied or pulsed power includes increasing the power supplied to a lamp or group of lamps from the initial amount of power to an increased amount of power for specific lamps or groups of lamps and then returning the amount of power supplied to the initial amount of power supplied. The frequency at which the power is cycled is based on the angular position of the substrate support 607 determined by the controller 238. For example, the thermal energy from a group of lamps of the upper lamp module 108 changes based on the angular position of the substrate support 607.

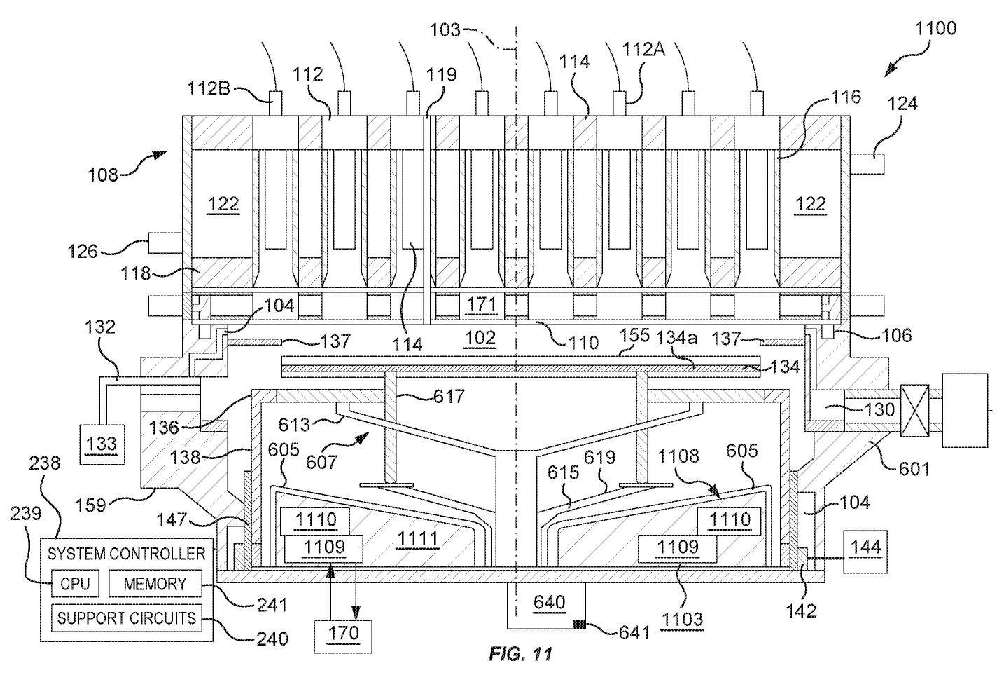

FIG. 11 illustrates a schematic cross-sectional view of a processing chamber 1100, position according to one or more embodiments. The processing chamber 1100 includes the chamber body 601 that defines the processing region 102, the central axis 103, the upper lamp module 108, and a cooling module 1103. The processing chamber 1100 can be a reduced-pressure or vacuum chamber.

In some embodiments, the processing chamber 1100 functions as an epitaxy deposition chamber configured to deposit one or more layers of materials on a substrate 134. In some embodiments, the processing chamber 1100 functions as a rapid thermal processing (RTP) chamber. The upper lamp module 108 is described above in relation to FIGS. 1 and 2. The substrate support 607, the lift mechanism 640, and the substrate lift 615 are described above in relation to FIG. 6.

The cooling module 1103 is disposed on a bottom side of the chamber body 601. The cooling module 1103 is separated from the processing region 102 by a plate 1105. The cooling module 1103 includes a plurality of cooling channels 1108. The plurality of cooling channels 1108 include a first cooling channel 1109 and a second cooling channel 1110. The first cooling channel 1109 and the second cooling channel 1110 are disposed in a cooling cavity region 1111 separated from the processing region 102 by the plate 1105. The cooling cavity region 1111 can include an open space or regions that include filler materials, such as a metal or ceramic material. The temperature of the plate 1105 may be controlled independently by the controller 238 to provide desired temperature profile across the substrate 134. The controller 238 may further translate the substrate support 607 closer to or farther away from the plate 1105 to control substrate temperature. For example, the controller 238 may cause the substrate 134 to rapidly cool by causing the substrate support 607 to bring the substrate 134 closer to the plate 1105.

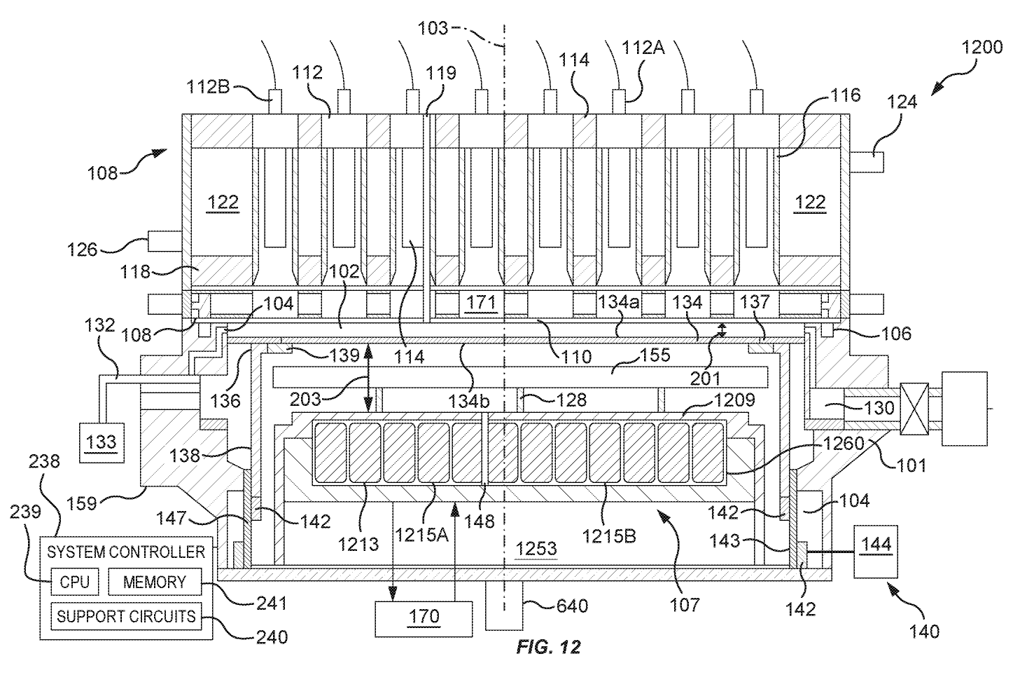

In some embodiments, the cooling module 1103 is coupled to the cooling system 170. The cooling system 170 is configured to maintain a temperature of the plate 1105. In such embodiments, the cooling system 170 includes a fluid source configured to supply a cooling medium, such as a liquid or a gas, which is recirculated through a heat exchanging element (not shown). The heat exchanging element is operable to adjust the temperature of the recirculated fluid, thereby controlling the thermal conditions (e.g., temperature) of the cooling cavity region 1111 and plate 1105.FIG. 12 illustrates a schematic cross-sectional view of a processing chamber 1200, position according to one or more embodiments.

In some embodiments, the processing chamber 1200 functions as an epitaxy deposition chamber configured to deposit one or more layers of materials on a substrate 134. In some embodiments, the processing chamber 1200 functions as a rapid thermal processing (RTP) chamber. In some embodiments, the processing chamber 1200 can be a reduced-pressure or vacuum chamber.

The processing chamber 1200 includes the chamber body 101, the substrate support 136, and the upper lamp module 108. The chamber body 101, the substrate support 136, and the upper lamp module 108 are described above in relation to FIGS. 1 and 2. The processing chamber 1200 also includes a cooling module 1207.

The cooling module 1207 is disposed on a bottom side of the chamber body 101. The cooling module 1207 is separated from the processing region 102 by a cooling plate 1209. The cooling module 1207 includes a plurality of coolers 1213. The plurality of coolers 1213 include a first cooler 1215A and a second cooler 1215B. The plurality of coolers 1213 may be any type of cooling device.

In some embodiments, the plurality of coolers 1213 have an orientation perpendicular to the central axis 103. The coolers 1213 may be disposed in a cooling cavity 1260 formed in cooling module 1207. The cooling module 1207 may be controlled independently by a controller 238 to provide desired temperature profile across the substrate 134. In some embodiments, the cooling module 1207 is coupled to a cooling system 170. In such embodiments, the cooling system 170 includes a fluid source configured to supply a cooling medium, such as a liquid or a gas, which is recirculated through a heat exchanging element (not shown). The heat exchanging element is operable to adjust the temperature of the recirculated fluid, thereby controlling the thermal conditions (e.g., temperature) of the cooling module 1207.

In some embodiments, a coolant is introduced into the cooling module 1207 to provide thermal regulation during operation. The coolant flows through the plurality of coolers 1213, thereby extracting heat and maintaining the coolers 1213 at a desired temperature. The coolant may be a liquid or a gas, depending on system design and process requirements. In certain embodiments, the coolant is continuously circulated through a closed-loop cooling circuit coupled to a heat exchanger (e.g., the cooling system 170) to maintain a stable temperature profile. This configuration allows efficient heat dissipation from the cooling module 1207 and promotes uniform temperature control across the associated processing components.

The cooling system 170 and the plurality of coolers 1213 are configured to control a temperature of the cooling plate 1209 and substrate 134 within the processing region 102. The cooling module 1207 is disposed below (backside) the substrate 134.

The magnetic lift mechanism 140 is coupled to the chamber body 101 and disposed proximate the cooling module 1207. In some embodiments, the cooling plate 1209 includes the support pins 128. The support pins 128 are described above in relation to FIGS. 1 and 2.

In some embodiments, the processing chamber 1200 is configured to deposit a silicon film and a silicon germanium film doped with carbon on the substrate 134 to form multi-layer stacks. In some embodiments, the processing chamber 1200 is configured to deposit a Si film at a temperature greater than 700 degrees Celsius and then reduce temperature rapidly to perform a SiGeC deposition at 650 degrees Celsius or less. The processing chamber 1200 enables a transition between a Si deposition temperature and a SiGeC deposition temperature in less than 20 seconds, for example in less than 10 seconds, for example, from 3 seconds to about 7 seconds.

A protective region 1253 is formed within the cooling module 1207. The processing region 102 and the protective region 1253 may have different environments, such as different gases, different gas pressures, and different temperatures. In some embodiments, the pressure of the protective region 1253 is higher than the processing region 102. The protective region 1253 is separated from the processing region 102 by the cooling plate 1209.

In some embodiments, the top environment control system 124 and the cooling system 170 are configured to control the temperature and pressure differential experienced by the top window 110 and the cooling plate 1209, respectively.

The processing chamber 1200 includes the controller 238 coupled with other components of the processing chamber 1200 and configured to operate the various components and processing operations of the processing chamber 1200. The memory 241 includes instructions that, when executed by one or more processors cause one or more operations to be conducted, the one or more operations include at least one of maintaining a temperature and pressure within the cooling module 1207 and the upper lamp module 108. The CPU can cause one or more operations to be conducted, the one or more operations comprise at least one of determining if a pressure differential exists between the processing region 102 compared to inside the cooling module 1207 or the upper lamp module 108, determining a temperature of the substrate 134, and determining a flow rate and pressure of processing gas through the inlet 130. When the computer instruction code is executed by the one or more processors 239, the one or more processors 239 controls the processing chamber 1200 to perform processes in accordance with the various methods disclosed herein.

As shown, the processing chamber 1200 is in the processing position. The magnetic lift mechanism 140 is configured to translate the substrate 134 and the substrate support 136 about 4 inches or more when the processing chamber 1200 changes from the transfer position to the processing position.

The second substrate surface 134b faces the cooling module 1207 and receives energy from the coolers 1213. In some embodiments, the processing chamber 1200 does not include the support pins 128 and the substrate can be brought into contact with the cooling plate 1209. The enables radiative cooling by pulling thermal energy from the processing region 102 and the substrate 134 and enables conductive cooling when the substrate 134 is in contact with the cooling plate 1209.

Benefits of the present disclosure include a high level of processing tuning, reduced processing region volume, enhanced deposition uniformity, and decreased operating cost. It is contemplated that one or more aspects disclosed herein may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber comprising:
a chamber body defining a central axis and having a processing region;
an upper lamp module disposed on a top side of the chamber body and separated from the processing region by a top window, the upper lamp module comprising:
a plurality of top lamps disposed around the central axis;
a bottom lamp module disposed on a bottom side of the chamber body and separated from the processing region by a bottom window, the bottom lamp module comprising:
a plurality of bottom lamps comprising:
a first bottom plurality of lamps; and
a second bottom plurality of lamps distributed azimuthally between one or more lamps of the first bottom plurality of lamps; and
a magnetic lift mechanism coupled to the chamber body, the magnetic lift mechanism comprising:
a lift ring;
an actuator coupled to the lift ring; and
a substrate support ring coupled to the lift ring, the actuator configured to translate the substrate support ring about parallel to the central axis and rotate the substrate support ring about the central axis.

2. The processing chamber of claim 1, wherein the plurality of top lamps and the plurality of bottom lamps have an orientation parallel to the central axis, and each lamp of the plurality of top lamps and the plurality of bottom lamps are disposed in a respective lamp tube, each lamp tube having a reflective inner surface.

3. The processing chamber of claim 1, wherein the magnetic lift mechanism is configured to translate the substrate support ring about 4 inches or more.

4. The processing chamber of claim 1, wherein the magnetic lift mechanism is configured to dispose the substrate support ring about 20 millimeters or closer to the top window when in a processing position.

5. The processing chamber of claim 1, wherein the bottom window includes a plurality of support pins extending from the bottom window toward the upper lamp module, each support pin comprising the same material as the bottom window and having a pin tip configured to contact a substrate during a transfer operation.

6. The processing chamber of claim 1, wherein the upper lamp module includes a top pyrometer disposed over the top window and the bottom lamp module includes a lower pyrometer disposed under the bottom window.

7. A processing chamber comprising:
a chamber body defining a central axis;
an upper lamp module comprising:
a plurality of top lamps disposed over a top window, the plurality of top lamps comprising a first group of lamps;
a bottom lamp module comprising:
a plurality of bottom lamps disposed under a bottom window, the plurality of bottom lamps comprising a second group of lamps;
a lift mechanism comprising:
a substrate support; and
an encoder; and
a controller comprising instructions that, when executed, cause a plurality of operations to be conducted, the plurality of operations comprising:
rotating the substrate support;
detecting an angular position of the substrate support with the encoder; and
applying thermal energy to a substrate disposed on the substrate support from a first group of lamps and a second group of lamps based on the angular position of the substrate support, the thermal energy from the first group of lamps changing based on the angular position of the substrate support.

8. The processing chamber of claim 7, wherein the first group of lamps is disposed in the upper lamp module and the second group of lamps is disposed in the bottom lamp module.

9. The processing chamber of claim 7, wherein the applying thermal energy further comprises applying over half of a total thermal energy with the plurality of bottom lamps.

10. The processing chamber of claim 7, wherein the thermal energy is applied in relation to a lift pin of the substrate support.

11. A method of substrate processing comprising:
disposing a substrate in a processing chamber comprising:
an upper lamp module having an upper plurality of lamps;
a bottom lamp module having a lower plurality of lamps; and
a substrate support disposed between the upper lamp module and the bottom lamp module;
translating the substrate to a processing position where the substrate is closer to the upper lamp module than to the bottom lamp module;
applying radiant energy simultaneously to the substrate with the upper plurality of lamps and the lower plurality of lamps, the radiant energy comprising:
a first energy from the upper plurality of lamps; and
a second energy from the lower plurality of lamps, the second energy being at least double the first energy; and
measuring a first temperature of a first substrate surface with a top pyrometer and a second temperature of a second substrate surface with a lower pyrometer.

12. The method of claim 11, wherein the measuring the first substrate surface and the second substrate surface occur simultaneously with applying the radiant energy.

13. The method of claim 11, wherein disposing the substrate in the processing chamber comprises disposing the substrate on a plurality of support pins, the plurality of support pins extending from a bottom window of the bottom lamp module.

14. The method of claim 11, wherein applying radiant energy further comprises:
applying the first energy in an azimuthal pattern from a first top plurality of lamps of the upper plurality of lamps disposed in a first group; and
tuning the first energy with a tuning lamp of the upper plurality of lamps.

15. The method of claim 11, wherein translating the substrate to a processing position includes translating the substrate a distance of 50 millimeters or more between a transfer position and the processing position.

16. A method of substrate processing comprising:
disposing a substrate on a substrate support in a processing chamber comprising:
an upper lamp module comprising:
a first group of lamps;
a second group of lamps disposed concentric with the first group of lamps, the second group of lamps comprising separated subgroups arranged at equal angular intervals;
a bottom lamp module; and
the substrate support disposed between the upper lamp module and the bottom lamp module, the substrate support comprising:
a lift;
a plurality of lift pins coupled to the lift; and
a plurality of pin arms coupled to the lift;
rotating the substrate support;
detecting an angular position of the substrate support; and
applying thermal energy to the substrate from the upper lamp module based on the angular position of the substrate support.

17. The method of claim 16, wherein the thermal energy from the second group of lamps of the upper lamp module changes based on the angular position of the substrate support.

18. The method of claim 16, wherein the thermal energy supplied from the second group of lamps changes based on a location of the plurality of pin arms.

19. The method of claim 16, wherein the thermal energy is applied azimuthally.

20. The method of claim 16, further comprising applying thermal energy to a portion of a preheat ring adjacent an inlet of the processing chamber with a third group of lamps.
